(19) United States
(12) Patent Application Publication
(10) Pub. No.: US 2026/0007010 A1
(43) Pub. Date: Jan. 1, 2026

(54) DISPLAY PANEL AND DISPLAY DEVICE

(71) Applicants: Chengdu BOE Optoelectronics Technology Co., Ltd., Chengdu, Sichuan (CN); BOE Technology Group Co., Ltd., Beijing (CN)

(72) Inventors: Shuo Li, Beijing (CN); Peng Hou, Beijing (CN); Ling Shi, Beijing (CN); Kun Rong, Beijing (CN)

(73) Assignees: Chengdu BOE Optoelectronics Technology Co., Ltd., Chengdu, Sichuan (CN); BOE Technology Group Co., Ltd., Beijing (CN)

(21) Appl. No.: 18/880,738

(22) PCT Filed: May 21, 2024
(86) PCT No.: PCT/CN2024/094323

§ 371 Date: Jan. 2, 2025

(30) Foreign Application Priority Data
Jun. 14, 2023 (CN) 202310706609.X

(51) Int. Cl. H10K 59/131; H10K 59/121; H10K 59/122; H10K 102/00

(52) U.S. Cl. CPC H10K 59/131; H10K 59/1213; H10K 59/1216; H10K 59/122; H10K 2102/351

(57) ABSTRACT

The present disclosure discloses a display panel and a display device. The display panel includes a first metal layer and an anode layer which are arranged on a base substrate in a stacked mode. Specifically, the first metal layer includes a first signal line, a second signal line and a third signal line which are arranged at equal intervals; and the orthographic projection of the second signal line on the base substrate at least partially overlaps with the anode layer.

### CROSS-REFERENCE TO RELATED APPLICATION

The present application claims a priority of the Chinese patent application No. 202310706609.X filed on Jun. 14, 2023, which is incorporated herein by reference in its entirety.

### FIELD

Embodiments of the present disclosure relate to a display panel and a display device.

### BACKGROUND

Organic light-emitting diode (OLED) display panels have been widely used due to their advantages such as self-luminous, low driving voltage, and fast response speed. An OLED display panel generally includes a plurality of pixel units, each pixel unit includes a light-emitting unit and a pixel circuit connected to the light-emitting unit, and the light-emitting unit includes an anode, a light-emitting layer on the anode, and a cathode on the light-emitting layer. Therefore, the flatness of the anode of the light-emitting unit affects the color separation of one light-emitting unit.

However, since the pixel circuit under the anode has relatively complex electronic components (such as transistors and storage capacitors) and wiring structures, the flatness of the anode is not good. Therefore, current display panels and display devices still need to be further improved.

### SUMMARY

The present application provides a display panel and a preparation method thereof.

According to a first aspect of the present application, a display panel is provided, the display panel including a first metal layer and an anode layer stacked on a base substrate, the first metal layer including a first signal line, a second signal line and a third signal line being arranged at equal intervals, an orthographic projection of the second signal line on the base substrate at least partially overlapping with the anode layer.

In some embodiments, the display panel has a first pixel circuit and a second pixel circuit alternately arranged along a first direction, and the first pixel circuit and the second pixel circuit are symmetrically arranged along a second direction;
the anode layer includes a first anode corresponding to a first sub-pixel and a second anode corresponding to a second sub-pixel; the first anode is symmetrical about a first boundary of the first pixel circuit, the second anode is symmetrical about a second boundary of the second pixel circuit, and the first boundary of the first pixel circuit is parallel to the second boundary of the second pixel circuit;
the second signal line includes a first portion corresponding to the first pixel circuit and a second portion corresponding to the second pixel circuit, and in an orthographic projection of the first portion and the second portion on the base substrate, a portion located in the first sub-pixel region is symmetrical about a first boundary of the first pixel circuit, and a portion located in the second sub-pixel region is symmetrical about a second boundary of the second pixel circuit.

In some embodiments, a distance between the first signal line and the second signal line is greater than or equal to 2.5 μm, or a distance between the second signal line and the third signal line is greater than or equal to 2.5 μm, and widths of the first signal line, the second signal line, and the third signal line are respectively greater than or equal to 2 μm.

In some embodiments, the display panel further includes a second metal layer, the second metal layer has a first auxiliary metal line, an orthographic projection of the first auxiliary metal line on the base substrate at least partially overlaps with an orthographic projection of the anode on the base substrate, and an overlapping area of a projection of the first auxiliary metal line and a projection of the third signal line on the base substrate is less than 20% of a projection of the third signal line on the base substrate.

In some embodiments, the first auxiliary metal line is disposed on a projection position of a first boundary of the first pixel circuit, and the first auxiliary metal line is symmetrical about the first boundary of the first pixel circuit, or the first auxiliary metal line is disposed on a second boundary of the second pixel circuit, and the first auxiliary metal line is symmetrical about the second boundary of the second pixel circuit.

In some embodiments, a width of the first auxiliary metal line is greater than or equal to 2 μm.

In some embodiments, the anode layer further includes a third anode corresponding to a third sub-pixel, an orthographic projection of the third anode on the base substrate partially overlaps with the first pixel circuit and the second pixel circuit respectively, and the third anode has a symmetry axis extending along the first direction;
a projection of the first signal line in the third anode region is of an integral structure.

In some embodiments, the base substrate further includes a first reset power line, a second reset power line and a third reset power line, and the first reset power line, the second reset power line and the third reset power line are connected in a mesh manner.

In some embodiments, the second metal layer further includes a second auxiliary metal line and a third auxiliary metal line, an orthographic projection of the second auxiliary metal line and an orthographic projection of the third auxiliary metal line on the base substrate at least partially overlap with an orthographic projection of the third anode on the base substrate, and the second auxiliary metal line and the third auxiliary metal line are symmetrically distributed along the second direction.

In some embodiments, the display panel further includes first to third gate layers sequentially stacked on the base substrate, the first to third gate layers are located between the base substrate and the first metal layer, and a projection of the third gate layer in the projection area of the third anode is symmetrical to a projection of the second metal layer in the projection area of the third anode along the first direction.

In some embodiments, the display panel further includes a pixel defining layer having first to third openings, the first opening corresponds to the first anode, the second opening corresponds to the second anode, and the third opening corresponds to the third anode.

The first opening and the second opening include 3 via holes in the projection area of the base substrate, and the third opening includes 1.5 via holes in the projection area of the base substrate.

In some embodiments, the first signal line is a driving power line of the display panel, the second signal line is an auxiliary driving power line, and the third signal line is a data signal line of the display panel.

In some embodiments, the first metal layer is a second source-drain layer, and the second metal layer is a first source-drain layer.

In some embodiments, the pixel circuit includes:
a first transistor having a gate electrode connected to a first reset signal line, a first electrode connected to a first reset power line, and a second electrode connected to a third node;
a second transistor having a gate electrode connected to a first gate signal line included in the display panel, a first electrode connected to a first node, and a second electrode connected to the third node;
a third transistor having a gate electrode connected to the first node, a
first electrode connected to a second node, and a second electrode connected to the third node;
a fourth transistor having a gate electrode connected to a second gate signal line included in the display panel, a first electrode connected to a data signal line included in the display panel, and a second electrode connected to the second node;
a fifth transistor having a gate electrode connected to a light-emitting control signal line, a first electrode connected to a driving power line included in the display panel, and a second electrode connected to the second node;
a sixth transistor having a gate electrode connected to the light-emitting control signal line, a first electrode connected to the third node, and a second electrode connected to the light-emitting unit;
a seventh transistor having a gate electrode connected to a second gate signal line included in the display panel, a first electrode connected to a second reset power line, and a second electrode connected to the light emitting unit;
an eighth transistor having a gate electrode connected to the second reset signal line, a first electrode connected to a third reset power line included in the display panel, and a second electrode connected to the second node;
a storage capacitor, wherein one end of the storage capacitor is connected to the driving power line, and the other end of the storage capacitor is connected to the first node.

According to a second aspect of the present disclosure, there is provided a display device including the display panel.

### BRIEF DESCRIPTION OF THE DRAWINGS

Other features, objects, and advantages of the present application will become more apparent upon reading the detailed description of the non-limiting embodiments with reference to the following drawings:

FIG. 1 is a partial structural diagram of a display panel according to an embodiment of the present disclosure;

FIG. 2 is a partial structural diagram of another display panel according to an embodiment of the present disclosure;

FIG. 3 is a partial structural schematic diagram of a corresponding first source-drain layer in FIG. 2;

FIG. 4 is a partial structural schematic diagram of a corresponding second source-drain layer in FIG. 2;

FIG. 5 is an equivalent circuit diagram of a pixel circuit according to an embodiment of the present application;

FIG. 6 is a timing diagram corresponding to FIG. 5;

FIG. 7 is a cross-sectional view of an AA (or BB) region according to an embodiment of the present application;

FIG. 8 is a cross-sectional view of another AA (or BB) region according to an embodiment of the present application;

FIG. 9 is a schematic structural diagram of a circuit according to an embodiment of the present application;

FIG. 10 is a schematic structural diagram of a circuit according to an embodiment of the present application;

FIG. 11 is a schematic diagram of partial superposition of an active layer, a first gate layer, a second gate layer and an oxide layer of a display panel according to an embodiment of the present disclosure;

FIG. 12 is a schematic diagram of partial superposition of an active layer, a first gate layer, a second gate layer, an oxide layer and a third gate layer of a display panel according to an embodiment of the present disclosure;

FIG. 13 is a schematic diagram of partial superposition of an active layer, a first gate layer, a second gate layer, an oxide layer, a third gate layer, a first source-drain layer and a second source-drain layer of a display panel according to an embodiment of the present disclosure;

FIG. 14 is a schematic diagram of partial superposition of an active layer, a first gate layer, a second gate layer, an oxide layer, a third gate layer, a first source-drain layer, a second source-drain layer, an anode layer and a pixel defining layer of a display panel according to an embodiment of the present disclosure;

FIG. 15 is a cross-sectional view of a CC region according to an embodiment of the present application;

FIG. 16 is a partial structural schematic diagram of a first source-drain layer according to an embodiment of the present application;

FIG. 17 is a schematic diagram of partial superposition of an active layer, a first gate layer, a second gate layer, an oxide layer, a third gate layer and a first source-drain layer of another display panel according to an embodiment of the present disclosure;

FIG. 18 is a partial schematic diagram of a first source-drain layer of another display panel according to an embodiment of the present disclosure;

FIG. 19 is a schematic diagram of partial superposition of an active layer, a first gate layer, a second gate layer, an oxide layer, a third gate layer, a first source-drain layer and a second source-drain layer of another display panel according to an embodiment of the present disclosure;

FIG. 20 is a schematic diagram of partial superposition of an active layer, a first gate layer, a second gate layer, an oxide layer, a third gate layer, a first source-drain layer, a second source-drain layer, an anode layer and a pixel defining layer of another display panel according to an embodiment of the present disclosure;

FIG. 21 is a schematic diagram of partial superposition of an active layer, a first gate layer, a second gate layer, an oxide layer, a third gate layer, and a first source-drain layer of another display panel according to an embodiment of the present disclosure;

FIG. 22 and FIG. 23 are partial overlapping schematic diagrams of a via hole and a pixel defining layer opening of a display panel in the related art;

FIG. 24 and FIG. 25 are partial overlapping schematic diagrams of a via hole and a pixel defining layer opening of a display panel according to an embodiment of the present application.

### DETAILED DESCRIPTION

In the following, only certain exemplary embodiments are briefly described. As can be appreciated by those skilled in the art, the described embodiments may be modified in various ways without departing from the spirit or scope of the present application, and different embodiments may be arbitrarily combined without conflict. Accordingly, the drawings and description are to be considered exemplary in nature and not limiting.

The transistors used in all embodiments of the present application are field effect transistors or other devices with the same characteristics, and the transistors used in the embodiments of the present application are mainly switch transistors according to functions in the circuit. Since the source electrode and the drain electrode of the switching transistor used herein are symmetrical, the source electrode and the drain electrode thereof are interchangeable. In embodiments of the present application, the source electrode is referred to as a first electrode, the drain electrode is referred to as a second electrode, or the drain electrode is referred to as a first electrode, and the source electrode is referred to as a second electrode. The intermediate terminal of the transistor is defined as a gate electrode, the signal input terminal is a source electrode, and the signal output terminal is a drain electrode. In addition, the switching transistor used in this embodiment of the present application may include any one of a P-type switching transistor and an N-type switching transistor, where the P-type switching transistor is turned on when the gate is at a low level, and is turned off when the gate is at a high level, and the N-type switching transistor is turned on when the gate is at a high level, and is turned off when the gate is at a low level. In addition, in each embodiment of the present application, the plurality of signals corresponds to a valid potential and an invalid potential, and the valid potential and the invalid potential only denote that the potential of the signal has two state quantities, and do not imply that the valid potential or the invalid potential in all the signals has a specific value.

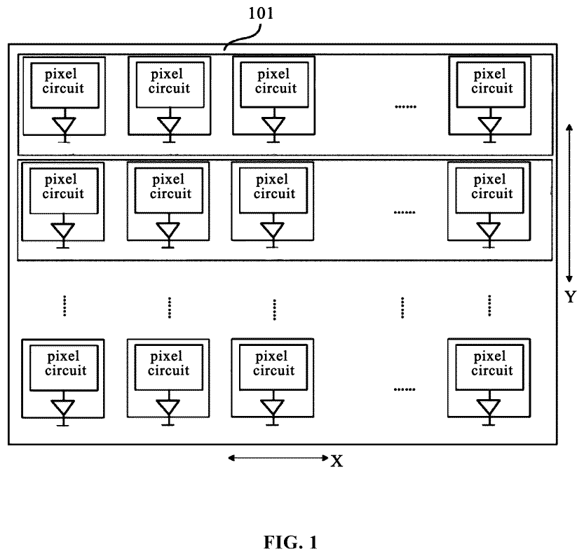

FIG. 1 is a partial structural schematic diagram of a display panel according to an embodiment of the present application. The display panel 10 may include a base substrate 101 and a plurality of pixel units 102.

At least one of the plurality of pixel units 102 includes a first sub-pixel, a second sub-pixel and a third sub-pixel. Herein, each of the first sub-pixel, the second sub-pixel and the third sub-pixel includes a pixel circuit and a light-emitting element. The pixel circuits in the first sub-pixel, the second sub-pixel and the third sub-pixel are respectively connected with the gate signal line, the data signal line and the light-emitting signal line. Specifically, the pixel circuits are configured to receive a data voltage transmitted by the data signal line and output a corresponding current to the light-emitting element under control of the gate signal line and the light-emitting signal line. The light-emitting elements of the first sub-pixel, the second sub-pixel and the third sub-pixel are respectively connected with the pixel circuit of the sub-pixel where the first sub-pixel, the second sub-pixel and the third sub-pixel are located. Specifically, the light-emitting elements are configured to emit light of corresponding brightness in response to a current outputted by the pixel circuit of the sub-pixel where the first sub-pixel, the second sub-pixel and the third sub-pixel are located.

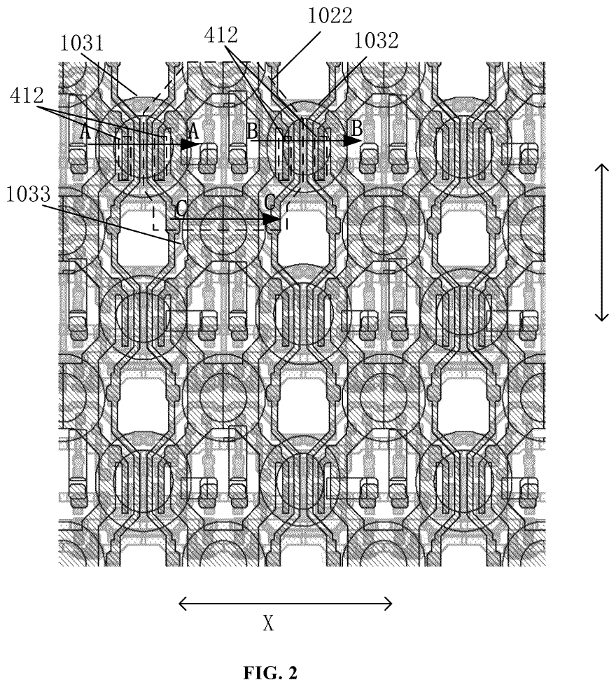

In a possible embodiment, FIG. 2 is a partial structural schematic diagram of another display panel according to an embodiment of the present application. As shown in FIG. 2, each of the plurality of pixel circuits arranged along the first direction X includes a plurality of first pixel circuits 1021 arranged along the second direction Y and a plurality of second pixel circuits 1022 arranged along the second direction Y. For example, the first direction X is a pixel row direction, and the second direction Y is a pixel column direction. The plurality of first pixel circuits 1021 and the plurality of second pixel circuits 1022 are alternately arranged along a first direction, and each of the plurality of first pixel circuits 1021 and the plurality of second pixel circuits 1022 includes a first boundary and a second boundary extending along a second direction.

In a possible embodiment, the pixel unit includes a red (R) sub-pixel, a green (G) sub-pixel, and a blue (B) sub-pixel. In some embodiments, the shape of the sub-pixel in the pixel unit is a rectangle, a diamond, a pentagon or a hexagon. The pixel units are arranged in a horizontally parallel manner, a vertically parallel manner, or a Chinese character “ [symbol] ” shape. FIG. 2 shows the positions of the first sub-pixel, the second sub-pixel and the third sub-pixel of the Chinese character “ [symbol] ” shape arrangement. Specifically, the first sub-pixel 1031 is a red sub-pixel, the second sub-pixel 1032 is a blue sub-pixel, and the third sub-pixel 1033 is a green sub-pixel.

It should be understood that the first pixel circuit 1021 and the second pixel circuit 1022 do not necessarily have a correspondence with the first sub-pixel and the second sub-pixel, that is, the first pixel circuit 1021 does not necessarily have a correspondence with the first sub-pixel 1031 connected thereto. In other words, the first pixel circuit 1021 is a pixel circuit configured to control the first sub-pixel 1031, or is a pixel circuit configured to control the third sub-pixel 1033, or a control circuit of another pixel, which is specifically determined according to a layout design of the pixel circuit, and is not specifically limited in the present application.

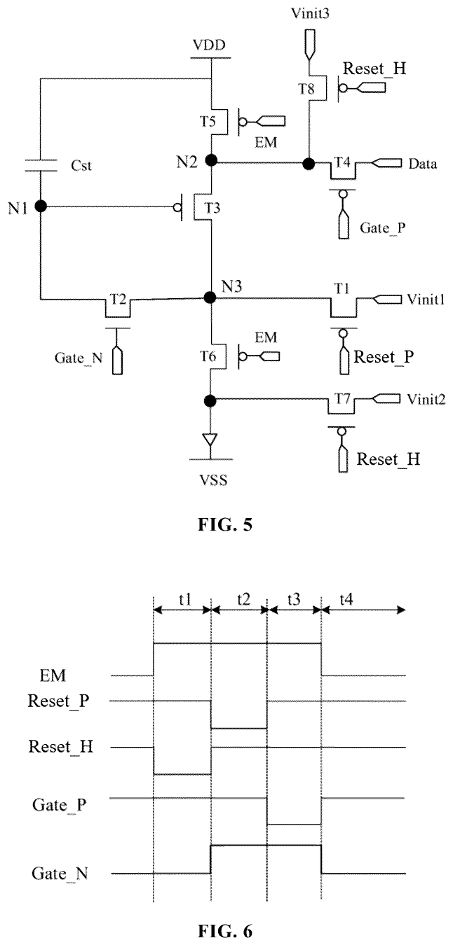

In a possible embodiment, the pixel circuit has a structure such as 3T1C, 4T1C, 5T1C, 5T2C, 6T1C or 7T1C. FIG. 5 is an equivalent circuit diagram of a pixel circuit according to an embodiment of the present application. As shown in FIG. 5, the pixel circuit may include a first transistor T1, a second transistor T2, a third transistor T3, a fourth transistor T4, a fifth transistor T5, a sixth transistor T6, a seventh transistor T7, an eighth transistor T8 and a storage capacitor Cst.

A gate electrode of the seventh transistor T7 is connected to the first reset signal line Reset_H, a first electrode of the seventh transistor T7 is connected to the second reset power line Vinit2, and a second electrode of the seventh transistor T7 is connected to the light emitting unit. The seventh transistor T7 is also referred to as a reset transistor.

A gate electrode of the fourth transistor T4 is connected to the first gate signal line Gate_P, a first electrode of the fourth transistor T4 is connected to the data signal line Data, and a second electrode of the fourth transistor T4 is connected to the second node N2. That is, the fourth transistor T4 is a data writing transistor in the pixel circuit.

A gate electrode of the fifth transistor T5 is connected to the light-emitting control signal line EM, a first electrode of the fifth transistor T5 is connected to the driving power supply line VDD, and a second electrode of the fifth transistor T5 is connected to the second node N2. Since the gate electrode of the fifth transistor T5 is connected to the light-emitting control signal EM, the fifth transistor T5 is also referred to as a light-emitting control transistor.

A gate electrode of the first transistor T1 is connected to the second reset signal line Reset_P, a first electrode of the first transistor T1 is connected to the first reset power line Vinit1, and a second electrode of the first transistor T1 is connected to the third node N3. The first transistor T1 is also referred to as a reset transistor.

A gate electrode of the sixth transistor T6 is connected to the light-emitting control signal line EM, a first electrode of the sixth transistor T6 is connected to the third node N3, and a second electrode of the fifth transistor T6 is connected to the light-emitting unit. Since the gate electrode of the sixth transistor T6 is connected to the light-emitting control signal line EM, the sixth transistor T6 is also referred to as a light-emitting control transistor.

A gate electrode of the second transistor T2 is connected to the second gate signal line Gate_N, a first electrode of the second transistor T2 is connected to the third node N3, and a second electrode of the second transistor T2 is connected to the first node N1. The second transistor T2 is also referred to as a compensation transistor.

A gate electrode of the third transistor T3 is connected to the first node N1, a first electrode of the third transistor T3 is connected to the second node N2, and a second electrode of the third transistor T3 is connected to the third node N3. The third transistor T3 is also referred to as a driving transistor.

The gate electrode of the eighth transistor T8 is connected to the first reset signal line Reset_H, that is, the gate electrode of the eighth transistor T8 and the gate electrode of the seventh transistor T7 share the first reset signal line Reset_H, the first electrode of the eighth transistor T8 is connected to the third reset power line Vinit3, and the second electrode of the eighth transistor T8 is connected to the second node N2. The eighth transistor T8 is also referred to as a reset transistor.

One end of the storage capacitor Cst is connected to the driving power line VDD, and the other end of the storage capacitor Cst is connected to the first node N1. Optionally, the storage capacitor Cst includes two capacitor plates Cst1 and Cst2, and in this embodiment of the present application, the capacitor plate Cst1 is referred to as one end, a first end, or a first storage capacitor electrode of the storage capacitor Cst, and the capacitor plate Cst2 is referred to as another end, a second end, or a second storage capacitor electrode of the storage capacitor Cst.

With reference to the above embodiments, in the embodiment of the present disclosure, the second transistor T2 is of an N-type transistor, and the first transistor T1, the third transistor T3, the fourth transistor T4, the fifth transistor T5, the sixth transistor T6 and the seventh transistor T7 are of all P-type transistors.

Optionally, each N-type transistor described in this embodiment of the present application is of an oxide transistor, and each P-type transistor is of a low-temperature polysilicon (LTPS) transistor. The oxide material may include indium gallium zinc oxide (IGZO), that is, the oxide transistor is an IGZO transistor. The pixel circuit formed by the eight (8) transistors is also referred to as an LTPO pixel circuit. The display panel in which the pixel circuit is the LTPO pixel circuit is referred to as an LTPO display panel.

Taking the pixel circuit shown in FIG. 5 with the first potential being a high potential relative to the second potential as an example, the driving principle of the pixel circuit described in the embodiments of the present disclosure will be described as follows. The timing is shown in FIG. 6.

In the initialization phase t1, the potential of the second reset signal provided by the second reset signal line Reset_P, the potential of the first gate driving signal provided by the first gate signal line Gate_P, and the potential of the light-emitting control signal provided by the light-emitting control signal line EM are all the first potentials. The potential of the second gate driving signal provided by the second gate signal line Gate_N and the potential of the first reset signal provided by the first reset signal line Reset_H are both second potentials. Accordingly, the seventh transistor T7 and the second transistor T2 are turned on. The fourth transistor T4, the fifth transistor T5, the first transistor T1, the sixth transistor T6, the second transistor T2, and the third transistor T3 are all turned off. In this way, the second reset signal having the second potential provided by the second reset power line Vinit2 is transmitted to the anode of the light emitting unit through the turned-on seventh transistor T7, and the third reset signal having the second potential provided by the third reset power line Vint3 is transmitted to the second node N2 through the turned-on eighth transistor T8, so as to reset the anode of the light emitting unit and the second node N2.

In the compensation phase t2, the potential of the second reset signal provided by the second reset signal line Reset_P jumps to the second potential, the potential of the second gate driving signal provided by the second gate signal line Gate_N jumps to the first potential, and the potential of the light-emitting control signal provided by the light-emitting control signal line EM remains at the first potential. Accordingly, the first transistor T1, the second transistor T2 and the third transistor T3 are all turned on, and the seventh transistor T7, the fourth transistor T4, the fifth transistor T5, the sixth transistor T6 and the eighth transistor T8 are turned off. In this way, the first reset power signal is transmitted to N3 through the turned-on first transistor T1, and the second transistor T2 adjusts the potential of the first node N1 based on the potential of the third node N3. In addition, the reset power signal of the second potential provided by the first reset power supply line Vinit1 is transmitted to the first node NI through the first transistor T1 and the second transistor T2 that are turned on, so as to reset the first node N1.

In the writing phase t3, the potential of the second reset signal provided by the second reset signal line Reset_P jumps to the first potential, the first reset signal provided by the first reset signal line Reset_H remains at the first potential, the potential of the first gate driving signal provided by the first gate signal line Gate_P jumps to the second potential, the second gate signal line Gate_N remains at the first potential, and the potential of the light-emitting control signal provided by the light-emitting control signal line EM remains at the first potential. Under the bootstrap effect of the storage capacitor Cst, the potential of the first node N1 is maintained at the second potential. Accordingly, the second transistor T2, the third transistor T3 and the fourth transistor T4 are turned on, and the first transistor T1, the fifth transistor T5, the sixth transistor T6, the seventh transistor T7 and the eighth transistor T8 are all turned off. In this way, the data signal line provided by the data signal line Data can be transmitted to the first node N1 sequentially through the fourth transistor T4, the third transistor T3 and the second transistor T2 that are turned on.

In the light emitting phase t4, the potential of the second reset signal provided by the second reset signal line Reset_P remains at the first potential, the first reset signal provided by the first reset signal line Reset_H remains at the first potential, the potential of the first gate driving signal provided by the first gate signal line Gate_P jumps to the second potential, the second gate signal line Gate_N jumps to the second potential, and the potential of the light emitting control signal provided by the light emitting control signal line EM jumps to the second potential. Under the bootstrap effect of the storage capacitor Cst, the potential of the first node N1 is maintained at the second potential of the data signal line Data. Accordingly, the third transistor T3, the fifth transistor T5 and the sixth transistor T6 are turned on, and the first transistor T1, the second transistor T2, the fourth transistor T4, the seventh transistor T7 and the eighth transistor T8 are all turned off. In this way, the driving power signal provided by the driving power line VDD is transmitted to the second node N2 through the turned-on fifth transistor T5, and the third transistor T3 can transmit the driving current to the third node N3 based on the potential of the first node N1 and the potential transmitted to the second node N2. Then, the driving current is transmitted to the anode of the light-emitting unit through the turned-on sixth transistor T6, a voltage difference is generated between the anode and the cathode of the light-emitting unit, which results in the light-emitting unit emitting light. The cathode layer is connected to the driving power line VSS.

In a possible embodiment, the light-emitting element is an organic electroluminescent diode (OLED) including an anode layer, an organic light-emitting layer, and a cathode layer. As described above, the flatness of the anode layer of the light-emitting element affects the color separation when the light-emitting element emits light.

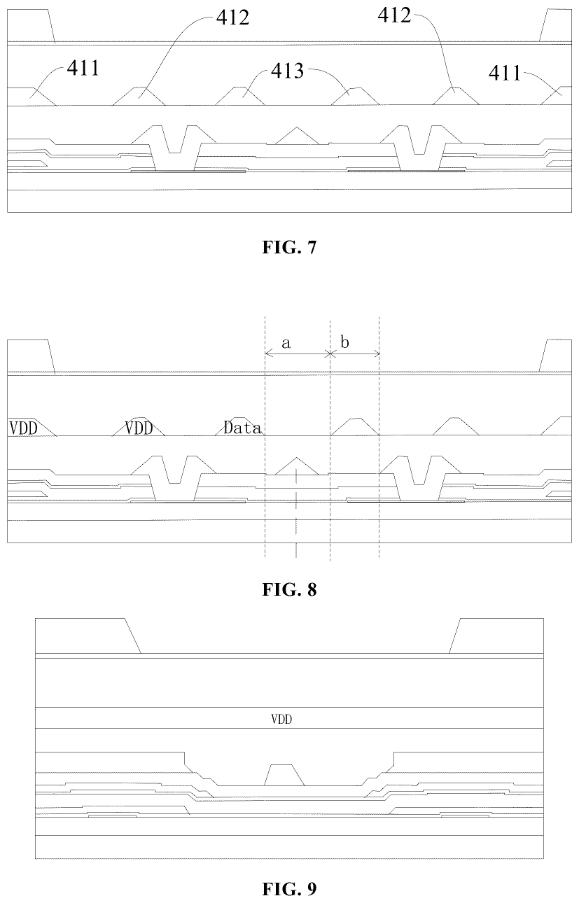

FIG. 7 is a partial cross-sectional view of FIG. 2 in the AA region. As shown in FIG. 7, the display panel includes a first metal layer and an anode layer (not shown in the figure), the first metal layer has a first signal line 411, a second signal line 412 and a third signal line 413 arranged at equal intervals, and an orthographic projection of the second signal line 412 on the base substrate at least partially overlaps with the anode layer.

Therefore, the anode layer of the light-emitting element can exhibit a better planarization effect under the supporting effect of the first signal line, the second signal line and the third signal line.

It should be particularly noted herein that, in the present application, the structures such as the first to third signal lines and the metal lines and other film layers, such as the anode layer “overlapping” or “partially overlapping”, particularly refer to that there is an overlapping or partially overlapping position relationship between the orthographic projections of two elements on the base substrate, rather than a direct contact stacking relationship between the two elements.

In a possible embodiment, the display panel may include an active layer Poly, a first gate insulating layer (GI) GI1, a first gate layer Gate1, a second gate insulating layer GI2, a second gate layer Gate2, an oxide layer Oxid, a third gate insulating layer GI3, a third gate layer Gate3, a first inter level dielectric (ILD) layer ILD0, a second ILD layer ILD, a first source-drain layer SD1, a first planarization layer (PLN) PLN1, a second source-drain layer SD2, a second planarization layer PLN2, a third planarization layer PLN 3, an anode layer (Anode), and a pixel definition layer (PDL) that constitute a pixel circuit and are sequentially stacked in a direction away from the base substrate 101.

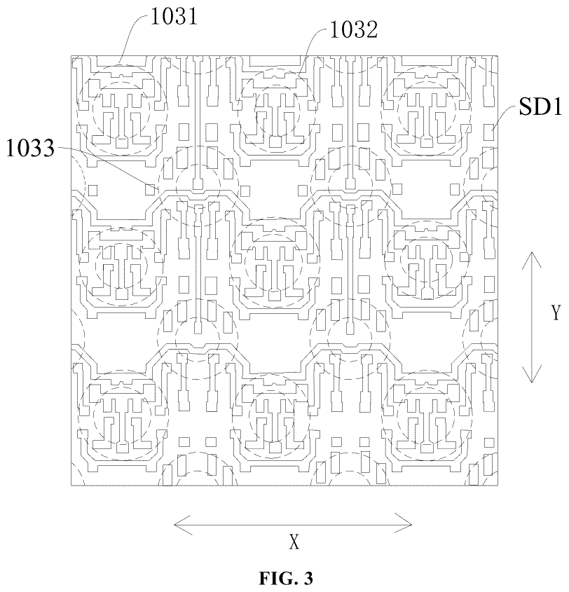

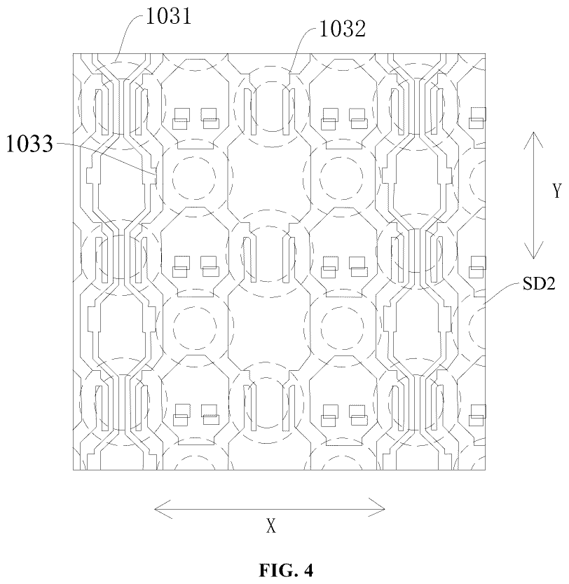

Exemplarily, the first metal layer is the second source-drain layer SD2, and the second metal layer is the first source-drain layer SD1. FIG. 3 and FIG. 4 respectively show schematic structural diagrams of a first source-drain layer and a second source-drain layer in FIG. 2.

Exemplarily, as shown in FIG. 8, the first metal layer is a second source-drain layer SD2, the first signal line 411 and the second signal line 412 is configured as a driving power line VDD, and the third signal line 413 is configured as a data signal line Data.

It should be noted that FIG. 2 further shows that the first pixel circuit 1021 and the second pixel circuit 1022 are alternately disposed along the first direction, the first pixel circuit 1021 and the second pixel circuit 1022 are symmetrical along the second direction, the anode layer includes a first anode 1031 corresponding to the first sub-pixel and a second anode 1032 corresponding to the second sub-pixel, the first anode 1031 is symmetrical about a first boundary of the first pixel circuit 1021, the second anode 1032 is symmetrical about a second boundary of the second pixel circuit 1022, and the first boundary of the first pixel circuit 1021 is parallel to the second boundary of the second pixel circuit 1022.

Further, the second signal line 412 includes a first portion corresponding to the first pixel circuit 1021 and a second portion corresponding to the second pixel circuit 1022, portions of orthographic projections of the first portion and the second portion on the base substrate located in the first sub-pixel region are symmetrical with respect to the first boundary of the first pixel circuit 1021, and portions of orthographic projections of the first portion and the second portion on the base substrate located in the first sub-pixel region are symmetrical with respect to the second boundary of the second pixel circuit 1022.

In a possible embodiment, as shown in FIG. 8, a distance between two adjacent third signal lines, a distance between the first signal line and the second signal line, or a distance between the second signal line and the third signal line are the same (as illustrated by reference numeral “a” in FIG. 8) and greater than or equal to 2.5 μm, and widths of the first signal line, the second signal line, and the third signal line are the same (as illustrated by reference numeral “b” in FIG. 8) and greater than or equal to 2 μm.

Therefore, in the embodiment of the present disclosure, the second signal line is additionally disposed on the second source-drain layer SD2 under the first sub-pixel and the second sub-pixel, thereby effectively increasing the overlapping area between the second source-drain layer SD2 and the anode layer, and improving the flatness of the anodes corresponding to the first sub-pixel and the second sub-pixel. In addition, the first metal layer having the symmetrical structure may further improve the flatness of the anode at the corresponding position(s), and provide a symmetrical metal wiring structure. Therefore, it is beneficial to further improve the performance of the display panel including the flatness, for example, providing a symmetrical pattern may provide a more consistent underlying structure in terms of a patterning process such as etching and a deposition process for forming a structure such as a light emitting layer, thereby improving the etching or deposition effect.

In a possible embodiment, the anode layer further includes a third anode 1033 corresponding to the third sub-pixel, the third anode 1033 partially overlaps with the first pixel circuit 1021 and the second pixel circuit 1022 respectively, and the third anode 1033 is symmetrical along the first direction. In order to further improve the performance of the display panel, the third anode 1033 is flattened and optimized after flattening the first sub-pixel 1031 and the second sub-pixel 1032 on the basis of the flattening process regarding the second source-drain layer SD2.

Optionally, a projection of the first signal line on the third anode is an integral structure. For example, FIG. 9 is a cross-sectional view of a CC region in FIG. 2 according to an embodiment of the present application. As shown in FIG. 9, the first signal line is configured as a driving power line VDD having an integral structure.

Therefore, in the embodiment of the present disclosure, the second signal line is added to the second source-drain layer SD2 in the projection region of the first sub-pixel and the second sub-pixel to enhance the flatness of the anodes of the first sub-pixel and the second sub-pixel, and the driving power line VDD of the second source-drain layer SD2 in the projection region of the third sub-pixel is set as an integral structure to enhance the flatness of the anodes of the third sub-pixel. Therefore, by improving the second source-drain layer SD2, the flatness of the anodes of the first sub-pixel, the second sub-pixel and the third sub-pixel can be improved respectively, thereby effectively avoiding color separation caused by unevenness of the anode(s).

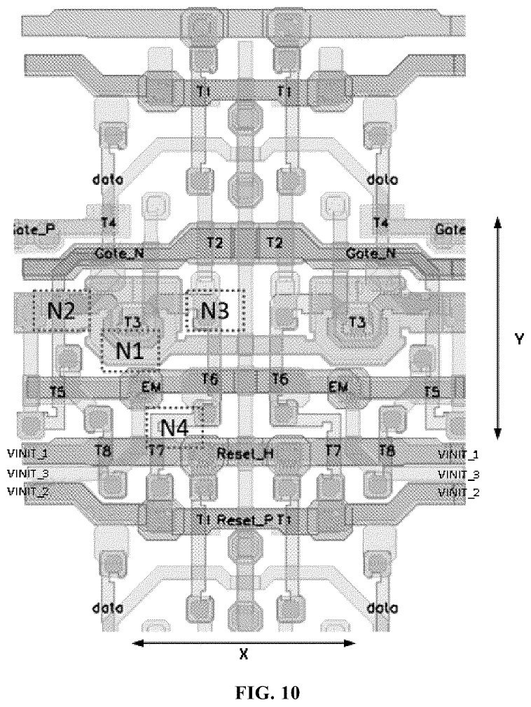

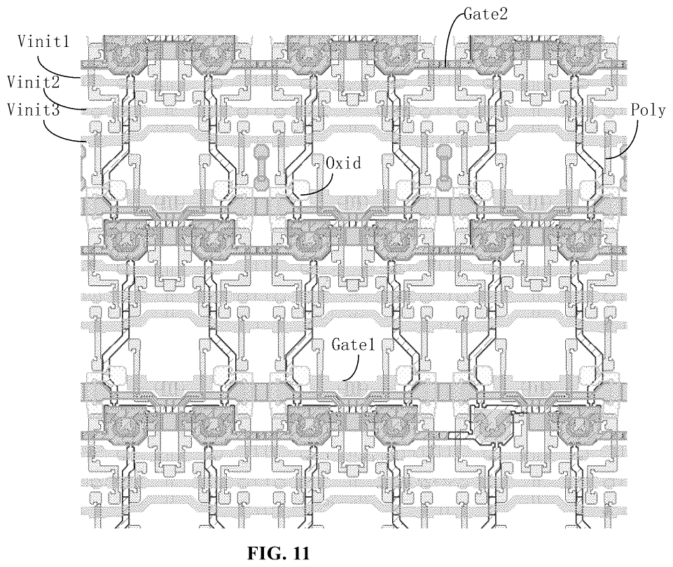

In a possible embodiment, FIG. 10 is a schematic structural diagram of a circuit according to an embodiment of the present application. The connection structure shown in FIG. 10 is a connection structure corresponding to the first pixel circuit 1021 and the second pixel circuit 1022 in FIG. 2. As shown in FIG. 10, under the first pixel circuit 1021 and the second pixel circuit 1022, the first reset power supply line Vinit1, the second reset power supply line Vinit2 and the third reset power supply line Vinit3 are configured as signal lines extending along the first direction X, and form a mesh connection with the signal lines extending along the second direction Y.

It should be noted that the data signal line Data and the driving power line VDD are vertical signal lines. Specifically, the horizontal signal line mainly provides signals for a plurality of pixel circuits arranged in the horizontal direction, and the vertical signal line mainly provides signals for a plurality of pixel circuits arranged in the vertical direction.

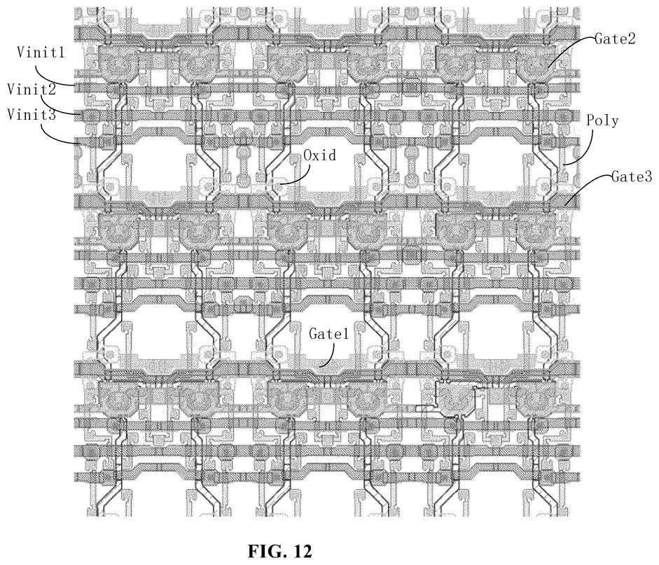

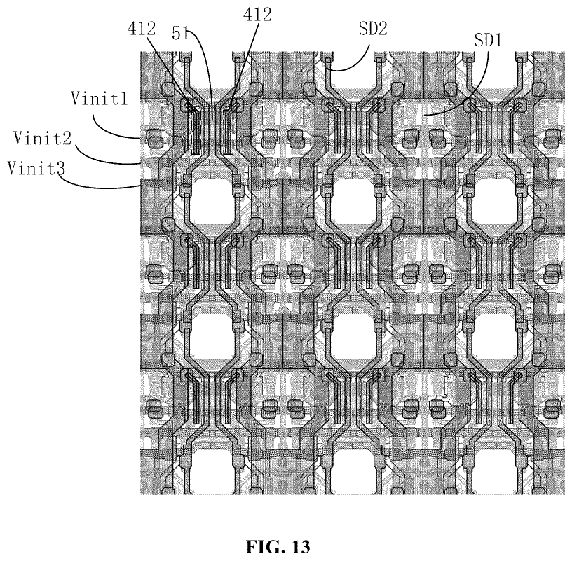

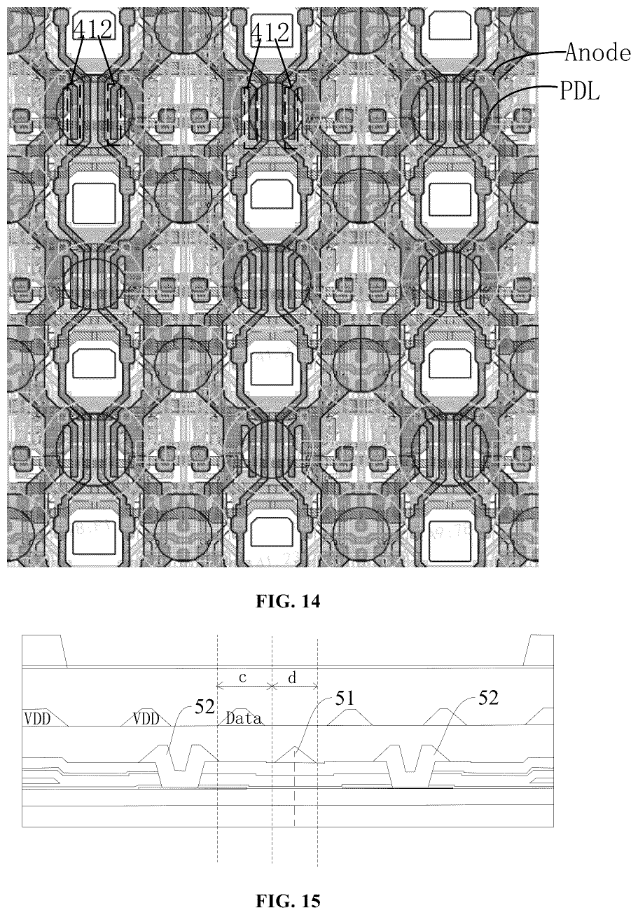

FIG. 11 is a schematic diagram of partial superposition of an active layer, a first gate layer, a second gate layer, and an oxide layer of a display panel according to an embodiment of the present application, where Vinit1, Vinit2, and Vinit3 are all formed by a first gate layer Gate1 metal. FIG. 12 is a schematic diagram of partial superposition of an active layer, a first gate layer, a second gate layer, an oxide layer, and a third gate layer of a display panel according to an embodiment of the present application, that is, a superposition position of the third gate layer is further shown on the basis of FIG. 11. FIG. 13 is a schematic diagram of partial superposition of an active layer, a first gate layer, a second gate layer, an oxide layer, a third gate layer, a first source-drain electrode, and a second source-drain electrode of a display panel according to an embodiment of the present application. FIG. 14 is a schematic diagram of partial superposition of an active layer, a first gate layer, a second gate layer, an oxide layer, a third gate layer, a first source-drain electrode layer, a second source-drain electrode layer, an anode layer, and a pixel defining layer of a display panel according to an embodiment of the present application. The stacking sequence of the above metal layers is as described above and will not be repeated here.

In a possible embodiment of the present application, since the flatness of the anode is strongly affected by the metal layer (the second source-drain layer SD2) closest to the anode, as the distance from the edge gets bigger and bigger, such an influence caused by the metal layer becomes smaller and smaller. Accordingly, the present application further proposes an optimization method for the wiring of the first source-drain layer SD1 to further enhance the flatness of the sub-pixel anode.

Optionally, a first auxiliary metal line is further disposed on the first source-drain layer SD1, the first auxiliary metal line at least partially overlaps with the anode, and an overlapping area of a projection of the first auxiliary metal line and the third signal line on the first source-drain layer SD1 is less than 20% of a projection area of the third signal line on the first source-drain layer SD1.

Exemplarily, as shown in FIG. 15, the first auxiliary metal line 51 is disposed on a symmetric line of the two data signal lines Data, and forms a complementary structure with the two data signal lines Data, to further enhance the flatness of the anode. Moreover, the first auxiliary metal wire 51 and the wiring structure in the original circuit form a wiring structure with uniform spacing, which increases the overlapping area of the first source-drain layer SD1 and the anode layer, and provides a stable basic structure for further improving the flatness of the anode.

Preferably, the structure of the first auxiliary metal line 51 is complementary to the structure of the two data signal lines Data, and the width (as illustrated by reference numeral “d” in FIG. 15) of the first auxiliary metal line 51 is greater than or equal to 2 μm. Furthermore, the first auxiliary metal wire 51 and the wiring structure in the original circuit form a wiring structure with uniform spacing, and the distance (as illustrated by reference numeral “c” in FIG. 15) between the first auxiliary metal line 51 and the wiring structure in the original circuit is greater than or equal to 1.5 μm.

It should be understood that since the first sub-pixel and the second sub-pixel are connected across the first pixel circuit and the second pixel circuit, the first auxiliary metal line is disposed on the projection position of the first boundary of the first pixel circuit and is symmetrical with respect to the first boundary of the first pixel circuit. Alternatively, the first auxiliary metal line is disposed on the second boundary of the second pixel circuit and is symmetrical with respect to the second boundary of the second pixel circuit.

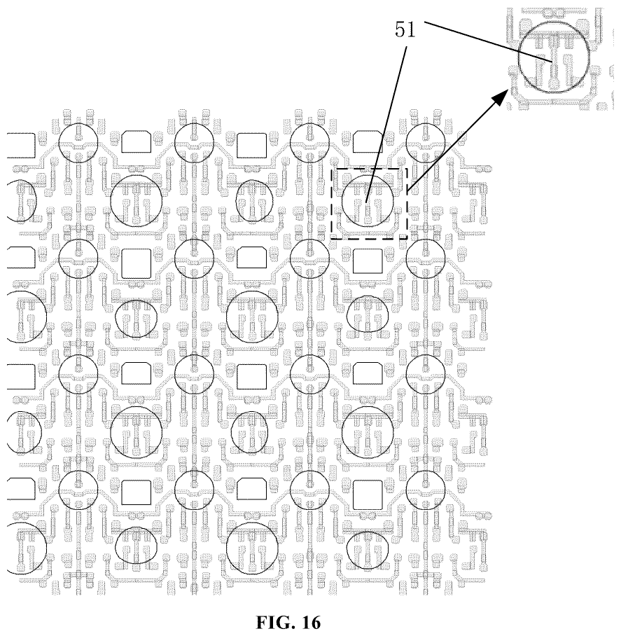

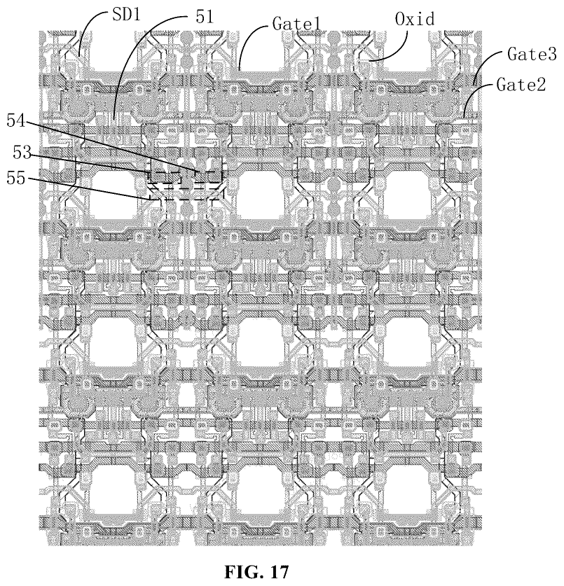

FIG. 16 is a schematic diagram of a partial structure of a first source-drain electrode layer according to an embodiment of the present disclosure, and FIG. 17 is a schematic diagram of partial superposition of an active layer, a first gate electrode layer, a second gate electrode layer, an oxide layer, a third gate electrode layer and a first source-drain electrode layer of another display panel according to an embodiment of the present disclosure.

Therefore, in this embodiment of the present application, the first auxiliary metal line is added to the first source-drain electrode layer SD1 in the projection region of the first sub-pixel and the second sub-pixel, so that an overlapping area between the first source-drain electrode layer SD1 and the anode is increased, thereby enhancing flatness of the first sub-pixel and the second sub-pixel anode, and effectively avoiding a color separation caused by uneven anode.

In a possible embodiment, similar to the second source-drain layer SD2, the first source-drain layer SD1 may also further perform planarization optimization on the third anode.

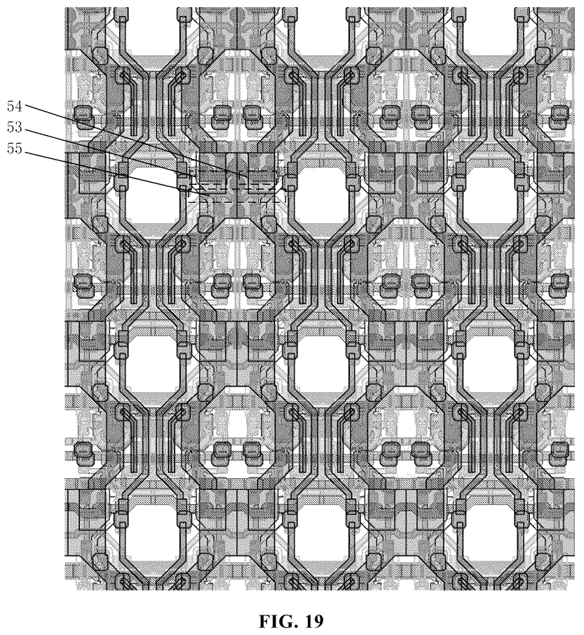

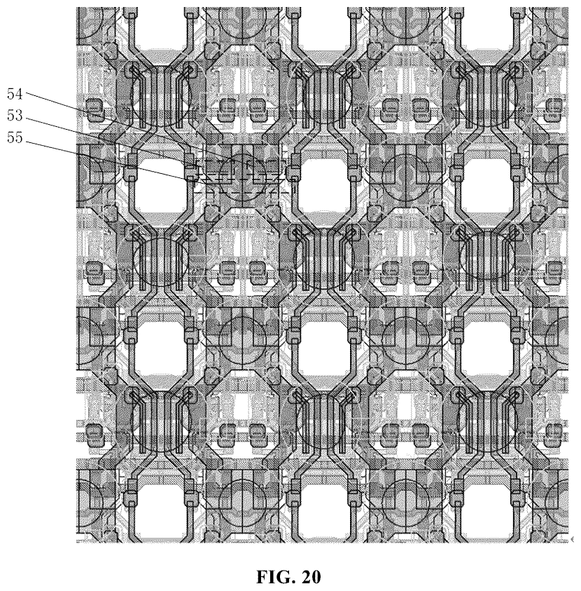

Optionally, referring to FIGS. 17-20, the first source-drain layer SD1 includes a second auxiliary metal line 53 and a third auxiliary metal line 54, the second auxiliary metal line 53 and the third auxiliary metal line 54 at least partially overlap with the third anode, and the second auxiliary metal line 53 and the third auxiliary metal line 54 are symmetrical along the second direction.

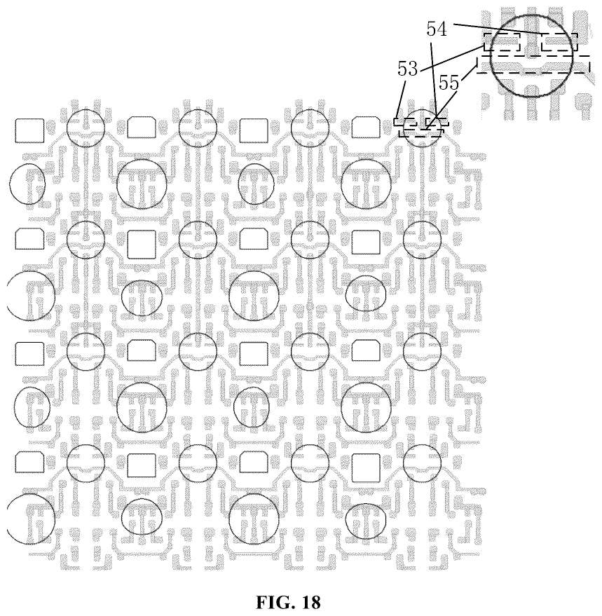

Exemplarily, as shown in FIG. 18, the second auxiliary metal line 53 and the third auxiliary metal line 54 are added to the projection area of the first source-drain layer SD1 on the third anode to form a symmetrical structure with the metal structure 55 in the original circuit, so as to uniformly support the third anode, thereby effectively improving the flatness of the third anode.

Further, since the bigger distance the metal layer is away from the anode, the smaller the influence is, in the case where the symmetry of the first source-drain SD1 in the first direction is poor, the third gate layer may also be used for compensation.

Optionally, a projection of the third gate layer in the projection area of the third anode is symmetrical to a projection of the second metal layer in the projection area of the third anode along the first direction.

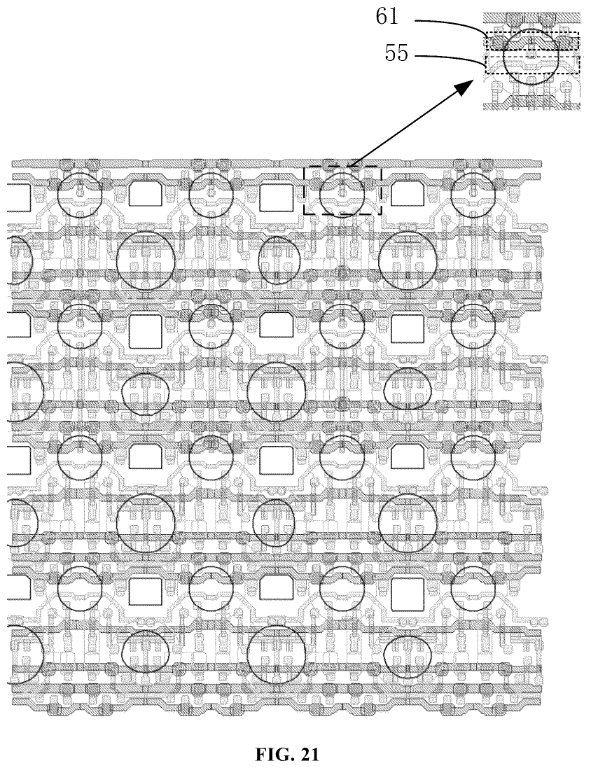

Exemplarily, as shown in FIG. 21, the projection 61 of the third gate layer in the projection area of the third anode is symmetrical with the projection 55 of the second metal layer in the projection area of the third anode in the first direction.

In a possible embodiment, in addition to optimizing the flatness of the anode through wires, the via hole of the interlayer dielectric layer ILD and the via hole design of the planarization layer (including the first planarization layer PLN1, the second planarization layer PLN2, and the third planarization layer PLN3) may also affect the flatness of the anode.

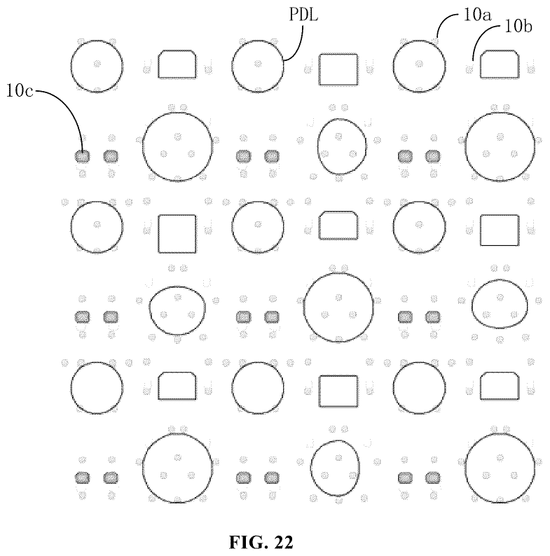

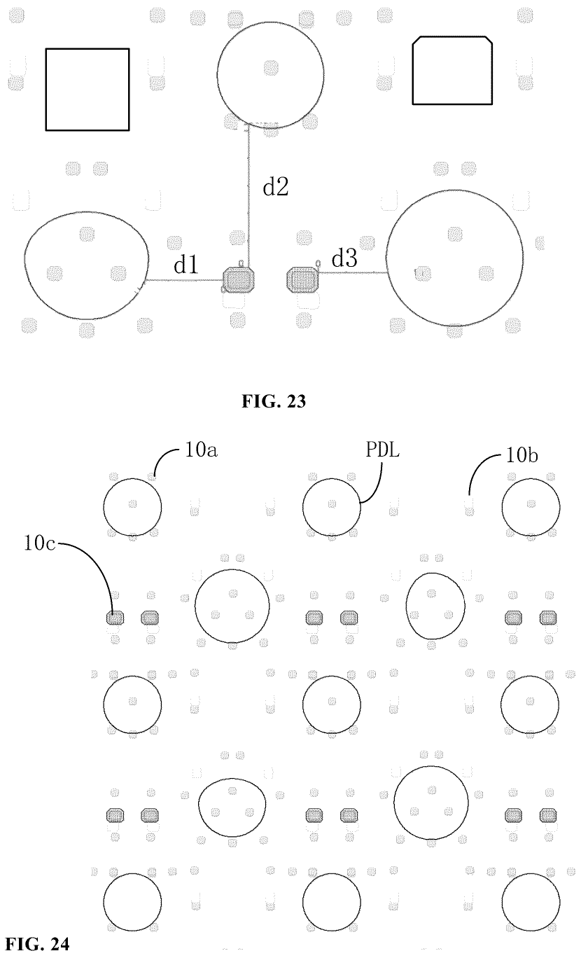

In the related art, as shown in FIG. 22 and FIG. 23, when the cross-sectional width of the opening of the pixel defining layer parallel to the display panel is 22 μm, the aperture ratio is 20.56%. The pixel defining layer (such as the reference numeral PDL shown in the figures) has a first opening corresponding to the first anode (the first sub-pixel region), a second opening corresponding to the second anode (the second sub-pixel region), and a third opening corresponding to the third anode (the third sub-pixel region). Herein, there are three (3) holes in the projection area of the first opening, there are 2.5 holes in the projection area of the second opening, and there are 4.5 holes in the projection area of the third opening. Accordingly, the second sub-pixel overlaps with the first planarization layer PLN1 by −0.3 μm, where the distance d1 from the boundary of the third planarization layer PLN3 to the boundary of the first opening is 13.6 μm, the distance d2 from the boundary of the third planarization layer PLN3 to the boundary of the second opening is 25.115 μm, and the distance d3 from the boundary of the third planarization layer PLN3 to the boundary of the third opening is 11.055 μm.

Those skilled in the art can understand that the 2.5 holes and 4.5 holes described above should be broadly understood. That is, a partial area of a certain via hole does not fall within a specific projection area, and a cross-sectional area of the via hole that does not fall within the projection area is 30%-70% of an overall cross-sectional area of the via hole, for example, 40%-60%.

In the embodiment of the present disclosure, the aperture ratio of the pixel defining layer is limited to 15.93% is that the projection areas of the first opening and the second opening include three (3) via holes, and the projection area of the third opening includes 1.5 via holes.

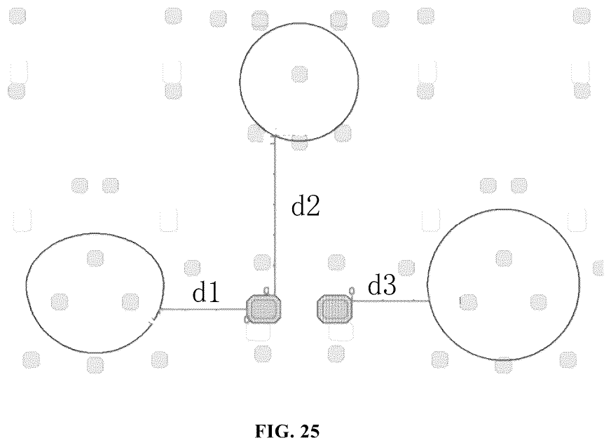

Exemplarily, as shown in FIG. 24 and FIG. 25, through the limited pixel defining layer, the projection area of the first opening includes three (3) via holes, the projection area of the second opening includes three (3) via holes, and the projection area of the third opening includes 1.5 via holes. The boundary of the second opening has a distance of +1.6 μm from the via boundary of the first planarization layer, the distance d1 from the boundary of the third planarization layer PLN3 to the boundary of the first opening is 14.25 μm, the distance d2 from the boundary of the third planarization layer PLN3 to the boundary of the second opening is 26.2 μm, and the distance d3 from the boundary of the third planarization layer PLN3 to the boundary of the third opening is 12.625 μm.

It should be particularly noted herein that the via holes (10a-10c as shown in the figures) are through holes formed in an interlayer dielectric layer (such as the first interlayer dielectric layer ILD0 and the second interlayer dielectric layer ILD described above) and the first planarization layer PLN1, the second planarization layer PLN2 and the third planarization layer PLN3 in order to achieve an electrical connection relationship between the metal wires and/or structures such as electrodes and active layers.

Therefore, by limiting the aperture ratio of the pixel defining layer, the number of via holes corresponding to the pixel opening projection area is further reduced, thereby achieving the purpose of improving the anode flatness. Meanwhile, the edge of the second sub-pixel opening is effectively prevented from overlapping with the via hole in the first planarization layer, and the flatness degree of the edge of the pixel anode is further improved.

In the description of the present specification, it should be understood that the orientation or position relationship indicated by the terms “upper”, “lower”, “front”, “rear”, “length”, “width”, “left”, “right”, “vertical”, “horizontal”, “top”, “bottom” and the like is based on the orientation or position relationship shown in the accompanying drawings, and is only for ease of description of the present application and simplification of description, rather than indicating or implying that the referred device or element must have a specific orientation, be constructed and operated in a specific orientation, and therefore cannot be understood as a limitation on the present application. For example, “upper” and “lower” describe the relative relationship of one component relative to another component, but these terms are used in this specification only for convenience, e.g., according to the directions of the examples described in the drawings. It will be appreciated that if the device of the icon is flipped upside down, the component recited “up” will become the component “down”. When a structure is “on” another structure, it may mean that the structure is integrally formed on the other structure, or that the structure is “directly” disposed on the other structure, or that the structure is “indirectly” disposed on the other structure through another structure. In addition, the terms “first” and “second” are used for descriptive purposes only, and cannot be understood as indicating or implying relative importance or implicitly indicating the number of technical features indicated. Thus, features defining “first” and “second” may explicitly or implicitly include one or more of the features. In the description of the present application, “a plurality of” means two or more, unless specifically defined otherwise.

In the present application, unless explicitly specified and limited otherwise, terms such as “installed”, “connected”, “connected”, and “fixed” should be understood broadly, for example, is a fixed connection, or is a detachable connection, or is integrated; is a mechanical connection, or is an electrical connection, or is communication; or is a direct connection, or is indirectly connected through an intermediate medium, or is internal communication between two elements or an interaction relationship between two elements. For a person of ordinary skill in the art, specific meanings of the foregoing terms in the present application is understood according to specific situations. In the present application, unless explicitly specified and defined otherwise, the “upper” or “lower” of the first feature on the second feature may include that the first and second features are in direct contact, or may include that the first and second features are not in direct contact but are in contact through another feature therebetween. Also, the first feature being “above”, “above”, and “above” the second feature includes the first feature being directly above and obliquely above the second feature, or merely indicating that the first feature is horizontally higher than the second feature. The first feature being “below”, “below”, and “below” the second feature includes the first feature being directly above and obliquely above the second feature, or merely indicating that the first feature is level less than the second feature.

The above application provides many different embodiments or examples for implementing different structures of the present application. In order to simplify the present application, components and settings of specific examples are described above. Of course, they are merely examples and are not intended to limit the present disclosure. In addition, the present application may repeat reference numerals and/or reference letters in different examples, such repetition being for purposes of simplicity and clarity and not by itself indicating relationships between various embodiments and/or settings discussed.

The above is only a specific implementation of the present application, but the protection scope of the present application is not limited thereto, and any person skilled in the art may easily conceive various changes or substitutions within the technical scope disclosed in the present application, all of which should be covered within the protection scope of the present application. Therefore, the protection scope of the present application shall be defined by the protection scope of the claims.

1. A display panel, comprising a first metal layer and an anode layer stacked on a base substrate;
wherein the first metal layer comprises a first signal line, a second signal line and a third signal line arranged at equal intervals;
wherein an orthographic projection of the second signal line on the base substrate at least partially overlaps with the anode layer.

2. The display panel according to claim 1, wherein the display panel has a first pixel circuit and a second pixel circuit alternately arranged along a first direction, and the first pixel circuit and the second pixel circuit are symmetrically arranged along a second direction;
the anode layer includes a first anode corresponding to a first sub-pixel and a second anode corresponding to a second sub-pixel; the first anode is symmetrical about a first boundary of the first pixel circuit, the second anode is symmetrical about a second boundary of the second pixel circuit, and the first boundary of the first pixel circuit is parallel to the second boundary of the second pixel circuit;
the second signal line includes a first portion corresponding to the first pixel circuit and a second portion corresponding to the second pixel circuit, and in an orthographic projection of the first portion and the second portion on the base substrate, a portion located in the first sub-pixel region is symmetrical about a first boundary of the first pixel circuit, and a portion located in the second sub-pixel region is symmetrical about a second boundary of the second pixel circuit.

3. The display panel according to claim 2, wherein a distance between the first signal line and the second signal line is greater than or equal to 2.5 μm; or a distance between the second signal line and the third signal line is greater than or equal to 2.5 μm, and widths of the first signal line, the second signal line and the third signal line are respectively greater than or equal to 2 μm.

4. The display panel according to claim 2, further comprising a second metal layer, wherein the second metal layer has a first auxiliary metal line, an orthographic projection of the first auxiliary metal line on the base substrate at least partially overlaps with an orthographic projection of the anode on the base substrate, and an overlapping area of projections of the first auxiliary metal line and the third signal line on the base substrate is less than 20% of a projection of the third signal line on the base substrate.

5. The display panel according to claim 4, wherein the first auxiliary metal line is disposed on a projection position of a first boundary of the first pixel circuit, and the first auxiliary metal line is symmetrical about the first boundary of the first pixel circuit; or the first auxiliary metal line is disposed on a second boundary of the second pixel circuit, and the first auxiliary metal line is symmetrical about the second boundary of the second pixel circuit.

6. The display panel according to claim 5, wherein a width of the first auxiliary metal line is greater than or equal to 2 μm.

7. The display panel according to claim 2, wherein the anode layer further comprises a third anode corresponding to a third sub-pixel, an orthographic projection of the third anode on the base substrate partially overlaps with the first pixel circuit and the second pixel circuit respectively, and the third anode has a symmetry axis extending along the first direction;
a projection of the first signal line in the third anode region is of an integral structure.

8. The display panel according to claim 2, wherein the base substrate further comprises a first reset power line, a second reset power line and a third reset power line, and the first reset power line, the second reset power line and the third reset power line are connected in a mesh manner.

9. The display panel according to claim 8, wherein the second metal layer further comprises a second auxiliary metal line and a third auxiliary metal line, an orthographic projection of the second auxiliary metal line on the base substrate and an orthographic projection of the third auxiliary metal line on the base substrate at least partially overlap with an orthographic projection of the third anode on the base substrate; and the second auxiliary metal line and the third auxiliary metal line are symmetrically distributed along the second direction.

10. The display panel according to claim 8, further comprising first to third gate layers sequentially stacked on the base substrate, wherein the first to third gate layers are located between the base substrate and the first metal layer, and a projection of the third gate layer in a projection area of a third anode is symmetrical to a projection of the second metal layer in the projection area of the third anode along the first direction.

11. The display panel according to claim 8, further comprising a pixel defining layer, wherein the pixel defining layer has first to third openings, the first opening corresponds to the first anode, the second opening corresponds to the second anode, and the third opening corresponds to the third anode;
the first opening and the second opening include 3 via holes in the projection area of the base substrate, and the third opening includes 1.5 via holes in the projection area of the base substrate.

12. The display panel according to claim 2, wherein the first signal line is a driving power line of the display panel, the second signal line is an auxiliary driving power line, and the third signal line is a data signal line of the display panel.

13. The display panel according to claim 1, wherein the first metal layer is a second source-drain layer, and the second metal layer is a first source-drain layer.

14. The display panel according to claim 1, wherein the pixel circuit comprises:
a first transistor having a gate electrode connected to a first reset signal line, a first electrode connected to a first reset power line, and a second electrode connected to a third node;
a second transistor having a gate electrode connected to a first gate signal line included in the display panel, a first electrode connected to a first node, and a second electrode connected to the third node;
a third transistor having a gate electrode connected to the first node, a first electrode connected to a second node, and a second electrode connected to the third node;
a fourth transistor having a gate electrode connected to a second gate signal line included in the display panel, a first electrode connected to a data signal line included in the display panel, and a second electrode connected to the second node;
a fifth transistor having a gate electrode connected to a light-emitting control signal line, a first electrode connected to a driving power line included in the display panel, and a second electrode connected to the second node;
a sixth transistor having a gate electrode connected to the light-emitting control signal line, a first electrode connected to the third node, and a second electrode connected to the light-emitting unit;
a seventh transistor having a gate electrode connected to a second gate signal line included in the display panel, a first electrode connected to a second reset power line, and a second electrode connected to the light emitting unit;
an eighth transistor having a gate electrode connected to the second reset signal line, a first electrode connected to a third reset power line included in the display panel, and a second electrode connected to the second node;
a storage capacitor, wherein one end of the storage capacitor is connected to the driving power line, and the other end of the storage capacitor is connected to the first node.

15. A display device, comprising the display panel according to claim 1.

16. The display device according to claim 15, wherein the display panel has a first pixel circuit and a second pixel circuit alternately arranged along a first direction, and the first pixel circuit and the second pixel circuit are symmetrically arranged along a second direction;
the anode layer includes a first anode corresponding to a first sub-pixel and a second anode corresponding to a second sub-pixel; the first anode is symmetrical about a first boundary of the first pixel circuit, the second anode is symmetrical about a second boundary of the second pixel circuit, and the first boundary of the first pixel circuit is parallel to the second boundary of the second pixel circuit;
the second signal line includes a first portion corresponding to the first pixel circuit and a second portion corresponding to the second pixel circuit, and in an orthographic projection of the first portion and the second portion on the base substrate, a portion located in the first sub-pixel region is symmetrical about a first boundary of the first pixel circuit, and a portion located in the second sub-pixel region is symmetrical about a second boundary of the second pixel circuit.

17. The display device according to claim 16, wherein a distance between the first signal line and the second signal line is greater than or equal to 2.5 μm; or a distance between the second signal line and the third signal line is greater than or equal to 2.5 μm, and widths of the first signal line, the second signal line and the third signal line are respectively greater than or equal to 2 μm.

18. The display device according to claim 16, further comprising a second metal layer, wherein the second metal layer has a first auxiliary metal line, an orthographic projection of the first auxiliary metal line on the base substrate at least partially overlaps with an orthographic projection of the anode on the base substrate, and an overlapping area of projections of the first auxiliary metal line and the third signal line on the base substrate is less than 20% of a projection of the third signal line on the base substrate.

19. The display device according to claim 18, wherein the first auxiliary metal line is disposed on a projection position of a first boundary of the first pixel circuit, and the first auxiliary metal line is symmetrical about the first boundary of the first pixel circuit; or
the first auxiliary metal line is disposed on a second boundary of the second pixel circuit, and the first auxiliary metal line is symmetrical about the second boundary of the second pixel circuit.

20. The display device according to claim 19, wherein a width of the first auxiliary metal line is greater than or equal to 2 μm.
